(19) United States
(12) Patent Application Publication
(10) Pub. No.: US 2015/0028410 A1
(43) Pub. Date: Jan. 29, 2015

(54) NON-VOLATILE MEMORY DEVICE AND METHOD FOR MANUFACTURING SAME

(71) Applicant: Kabushiki Kaisha Toshiba, Minato-ku (JP)

(72) Inventor: Hisashi KATO, Mie-ken (JP)

(73) Assignee: Kabushiki Kaisha Toshiba, Minato-ku (JP)

(21) Appl. No.: 14/202,547

(22) Filed: Mar. 10, 2014

(30) Foreign Application Priority Data
Jul. 25, 2013 (JP) 2013-154452

(51) Int. Cl. H01L 29/792; H01L 21/28

(52) U.S. Cl. CPC H01L 29/792; H01L 21/28008
USPC 257/324; 438/586

(57) ABSTRACT

According to an embodiment, a non-volatile memory device includes a memory cell unit, an interconnection layer and a control circuit. The memory cell unit includes a plurality of control electrodes stacked on an underlying layer, a semiconductor layer passing through the control electrodes in a first direction perpendicular to the underlying layer, and a memory film provided between the semiconductor layer and each of the control electrodes. The memory cell unit includes a first contact hole having wall faces in a stairs form. The interconnection layer is provided on the memory cell unit, and electrically connected thereto. The control circuit is provided in the underlying layer, and electrically connected to the interconnection layer via a first contact plug provided in a second contact hole. The second contact hole is provided in the peripheral portion adjacent to the memory cell unit, and includes a wall face with steps.

### CROSS-REFERENCE TO RELATED APPLICATION

This application is based upon and claims the benefit of priority from Japanese Patent Application No.2013-154452, filed on Jul. 25, 2013; the entire contents of which are incorporated herein by reference.

### FIELD

Embodiments are generally related to a non-volatile memory device and a method for manufacturing the same.

### BACKGROUND

Non-volatile memory devices as represented by NAND type flash memory are manufactured using semiconductor wafer processes. Also, the increase in capacity, the reduction in power consumption, and the reduction in cost have been achieved by progress in 2-dimensional micro-fabrication technology for wafer processes. However, massive equipment investment is required for further progress in micro-fabrication technology. Therefore, the development of memory devices is progressing with a 3-dimensional memory cell unit in which a plurality of memory layers is stacked.

### BRIEF DESCRIPTION OF THE DRAWINGS

FIGS. 1A and 1B are schematic cross-sectional views illustrating a non-volatile memory device according to a first embodiment;

FIGS. 2A to 7B are schematic cross-sectional views illustrating a process of manufacturing the non-volatile memory device according to the first embodiment; and

FIGS. 8A to 12B are schematic cross-sectional views illustrating the process of manufacturing a non-volatile memory device according to a second embodiment.

### DETAILED DESCRIPTION

According to an embodiment, a non-volatile memory device includes a memory cell unit, an interconnection layer and a control circuit. The memory cell unit includes a plurality of control electrodes stacked on an underlying layer, a semiconductor layer passing through the control electrodes in a first direction perpendicular to the underlying layer, and a memory film provided between the semiconductor layer and each of the control electrodes. The interconnection layer is provided on the memory cell unit, and electrically connected to the memory cell unit. The control circuit is provided in the underlying layer. The memory cell unit includes a first contact hole having wall faces in a stairs form, each end of the control electrodes being exposed in one of the wall faces, and the control circuit is electrically connected to the interconnection layer via a first contact plug provided in a second contact hole. The second contact hole is provided in the peripheral portion adjacent to the memory cell unit, and includes a wall face with steps.

Embodiments will now be described with reference to the drawings. The same numerals are applied to constituents that have already appeared in the drawings, and repetitious detailed descriptions of such constituents are omitted. Note that the drawings are schematic or simplified illustrations, and relationships between thicknesses and widths of parts and proportions in size between parts may differ from actual parts. Also, even where identical parts are depicted, mutual dimensions and proportions may be illustrated differently depending on the drawing.

### FIRST EMBODIMENT

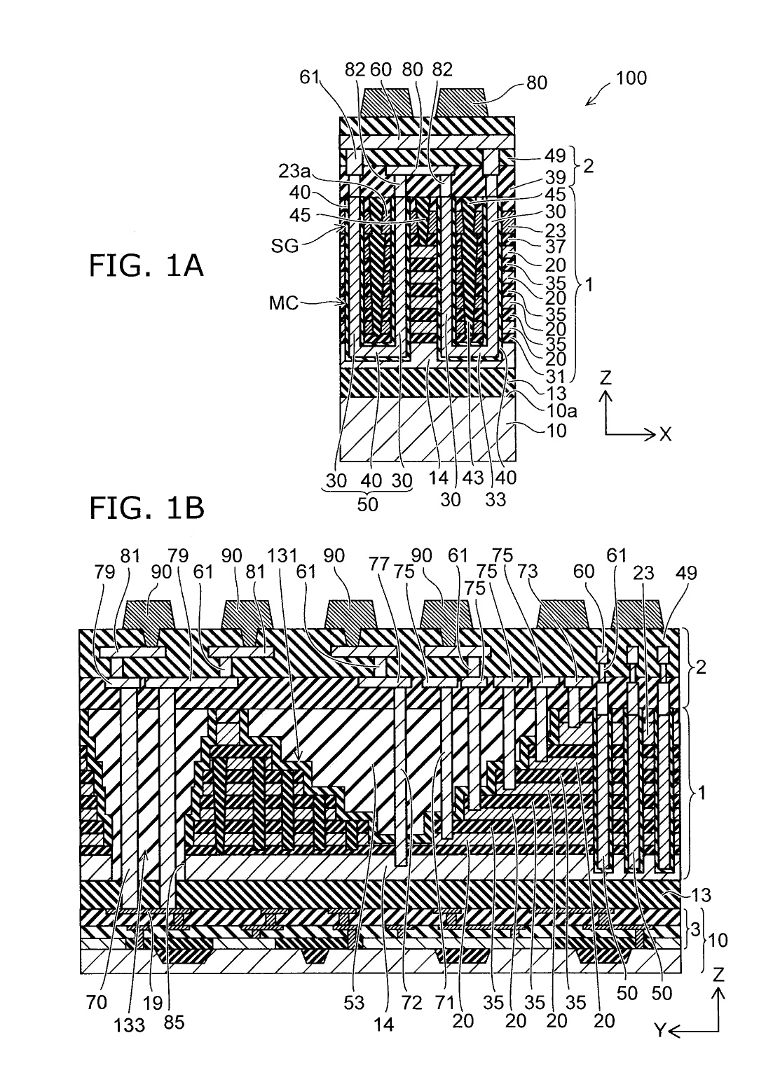

FIGS. 1A and 1B are schematic cross-sectional views illustrating a non-volatile memory device 100 according to a first embodiment. The non-volatile memory device 100 is, for example, a NAND type flash memory, that includes a memory cell unit with a 3-dimensional structure.

The non-volatile memory device 100 according to this embodiment includes a memory cell unit 1 provided on a substrate 10 that is a underlying layer, an interconnection layer 2 provided on the memory cell unit 1, and a circuit 3 provided on the substrate 10. The circuit 3 controls the memory cell unit 1 via the interconnection layer 2.

The memory cell unit 1 includes a plurality of control electrodes (hereinafter, a control gate electrode 20) stacked on the substrate 10, a semiconductor layer 30 that passes through the control gate electrodes 20 in a first direction perpendicular to the substrate 10, and a memory film 40 provided between the semiconductor layer 30 and the control gate electrode 20. Each control gate electrode 20 serves as a word line (WL).

Also, a first contact hole (hereinafter, a contact hole 131) is provided at an end of the memory cell unit 1. The contact hole 131 includes a step shaped wall face in which each end of the control gate electrodes 20 is exposed.

In addition, a second contact hole (hereafter, a contact hole 133) is provided in a peripheral portion adjacent to the memory cell unit 1. The contact hole 133 includes a first contact plug (hereinafter, a contact plug 70) that electrically connects the interconnection layer 2 and the circuit 3, that includes a wall face provided in a stairs form.

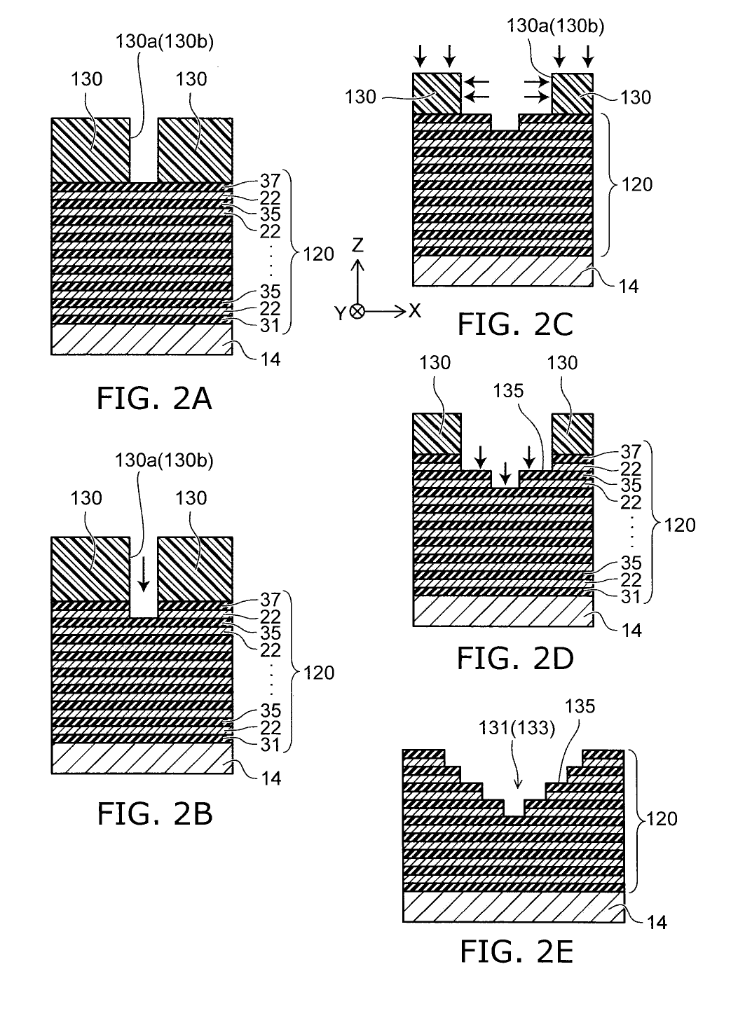

The following is a detailed explanation of the structure of the non-volatile memory device 100, which refers to FIGS. 1A and 1B. FIG. 1A illustrates a cross-section perpendicular to the word line (WL), and FIG. 2B illustrates a cross-section parallel to the WL. Also, a direction perpendicular to a top surface 10a of the substrate 10 (i.e. the first direction) is taken to be the Z-direction, and in a plane parallel to the top surface 10a, a direction perpendicular to the word line is taken to be the X-direction, and a direction parallel to the word line is taken to be the Y-direction.

As illustrated in FIG. 1A, the memory cell unit 1 is provided on the substrate 10 with an interlayer insulating film 13 inserted between the substrate 10 and the memory cell unit 1. The memory cell unit 1 includes a conductive layer 14 provided on the interlayer insulating film 13, the control gate electrodes 20 stacked on the conductive layer 14, and a selection gate electrode 23 provided on the control gate electrodes 20.

An insulating layer 31 is provided between the conductive layer 14 and the control gate electrode 20. Insulating layers 35 are provided between each of the control gate electrodes 20. An insulating layer 37 is provided between the control gate electrode 20 and the selection gate electrode 23. Each control gate electrode 20 includes, for example, polycrystalline silicon. The insulating layers 31, 35, and 37 include at least one of a silicon oxide film and a silicon nitride film, for example.

The control gate electrodes 20 are arranged in the X-direction, and an insulating film 43 is provided between the control gate electrodes 20 adjacent to each other in the X-direction. The selection gate electrodes 23 provided on the control gate electrodes 20 are arranged in the X-direction, and an insulating film 45 is provided between the selection gate electrodes 23 adjacent to each other.

In addition, the memory cell unit 1 includes a plurality of semiconductor layers 30 that pass through the insulating layer 31, the control gate electrodes 20, the insulating layer 35, the insulating layer 37, and the selection gate electrodes 23 in the Z-direction. A pair of semiconductor layers 30 respectively passes through the control gate electrodes 20 adjacent to each other in the X-direction. The one of the pair is electrically connected to the other with a connection member 33. The connection member 33 is provided between the conductive layer 14 and the control gate electrode 20.

The memory film 40 is provided between the semiconductor layer 30 and the control gate electrode 20, between the semiconductor layer 30 and the selection gate electrode 23, and between the semiconductor layer 30 and the conductive layer 14. The memory film 40 is, for example, a multilayer film that includes a silicon oxide film and a silicon nitride film. The memory film 40 is capable of storing charge injected from the semiconductor layer 30. In other words, a memory cell (MC) is formed in the portion where the semiconductor layer 30 and the control gate electrode 20 face each other with the memory film 40 inserted between the semiconductor layer 30 and the control gate electrode 20.

On the other hand, the memory film 40 is provided with a thickness for serving as a gate insulating film. Also, a selection gate transistor (SG) is formed between the semiconductor layer 30 and the selection gate electrode 23 that face each other with the memory film 40 inserted between the semiconductor layer 30 and the selection gate electrode 23. Also, the conductive layer 14 faces the conductive connection member 33 with the memory film 40 inserted between the conductive layer 14 and the connection member 33, and serves as a back gate.

In this way, the pair of semiconductor layers 30 that pass through adjacent control electrodes 20 is connected to each other by the connection member 33, and form a plurality of memory cells (MC), and an NAND string 50 that includes the selection gate transistor (SG) provided on both sides thereof.

The interconnection layer 2 is provided on the memory cell unit 1. The interconnection layer 2 includes a plurality of interconnections, and insulating films 39 and 49 that insulate the interconnections from each other. The interconnection layer 2 includes, for example, a bit line 60 and a source line 80, that are electrically connected to an end of the NAND string 50 via contact plugs 61 and 82, respectively.

As illustrated in FIG. 1B, the memory cell unit 1 includes a plurality of the NAND strings 50 arranged in the Y-direction along the word line (a control gate electrode 20). Also, as illustrated in FIG. 1A, the NAND strings 50 are provided so as to straddle over the adjacent control gate electrodes 20, and are arranged in the X-direction. In other words, the memory cell unit 1 has a three-dimensional structure that includes the plurality of NAND strings 50 extending in the Z-direction and disposed within the X-Y plane.

The memory cell unit 1 includes the contact hole 131 provided, for example, in an end of the memory cell unit 1. The wall face of the contact hole 131 is provided with a stairs form, and an end of the word line (the control gate electrode 20) is exposed in each step of the wall face. Here, “exposed” refers to the state where the interconnection layer or the word line above is removed, and, for example, may include the state in which an exposed electrode is covered with an insulating film.

On the other hand, the interconnection layer 2 includes a plurality of gate interconnections 75 (second interconnections). The contact hole 131 includes a plurality of contact plugs 71 (second contact plugs). Each contact plug 71 electrically connects the end of control gate electrode 20 exposed on the wall face of the contact hole 131 and the gate interconnection 75. Each contact plugs 71 passes through an insulating film 53 embedded in the contact hole 131 in the Z-direction, and contacts an end of the control gate electrode 20.

Also, the interconnection layer 2 includes gate interconnection 73 and 77 (third interconnections). The gate interconnection 73 is electrically connected to the selection gate electrode 23. The control gate transistor SG controls the NAND string 50 to be on or off-state according to a signal provided via the gate interconnection 73. On the other hand, the gate interconnection 77 is electrically connected to the conductive layer 14 exposed in the bottom face of the contact hole 131 via a contact plug 72 (a third contact plug). In this way, the conductive layer 14 serves as a back gate, and controls the electrical resistance of the connection member 33.

In addition, the contact hole 133 is provided in the peripheral portion adjacent to the memory cell unit 1, within a plane parallel to the top surface 10a of the substrate 10. The contact hole 133 includes the contact plug 70. The contact plug 70 electrically connects the circuit 3 provided on the top surface side of the substrate 10 and interconnection 79 (first interconnection) included in the interconnection layer 2. The contact plug 70 passes through insulating film 54 embedded in the contact hole 133 in the Z-direction, and contacts a terminal 19 of the circuit 3. Also, the contact hole 133 is formed at the same time as the contact hole 131, and the wall face of the contact hole 133 includes stairs-shaped steps.

The circuit 3 is electrically connected to the memory cell unit 1 via the contact plug 70 and the interconnection layer 2, and controls the operation of the memory cell unit 1. The substrate 10 is, for example, a silicon substrate. The circuit 3 includes, for example, a row decoder, a sense amplifier, and the like provided on the silicon substrate.

The interconnection layer 2 further includes intermediate interconnection 81. The intermediate interconnection 81 is connected to each gate interconnection via a contact plug 61. Also, the intermediate interconnection 81 is connected to a pad electrode 90 provided on the top surface of the interconnection layer 2.

Next, the method for manufacturing the non-volatile memory device according to this embodiment is described with reference to FIGS. 2 to 7. FIGS. 2A to 7B are schematic cross-sectional views illustrating the process of manufacturing the non-volatile memory device 100 according to the first embodiment.

First, as illustrated in FIG. 2A, a mask 130 (a first mask) is formed on the top surface of a stacked body 120. The stacked body 120 is provided on the substrate 10 with the interlayer insulating film 13 and the conductive layer 14 between the stacked body 120 and the substrate 10. The stacked body 120 includes, for example, the insulating layer 31, alternately stacked conductive layers 22 and insulating layers 35, and the insulating layer 37. The conductive layers 22 are, for example, polycrystalline silicon layers. The conductive layers 22 are divided by the insulating film 43 into stripe shaped word lines (the control gate electrodes 20).

The mask 130 is, for example, an organic film such as a photoresist or the like. Also, the mask 130 includes a first opening (hereinafter, an opening 130a) and a second opening (hereinafter, an opening 130b) at the positions corresponding to the contact holes 131 and 133, respectively. The sizes of the opening 130a and the opening 130b are the same as the sizes of the bottom faces of the contact holes 131 and 133 respectively.

Next, as illustrated in FIG. 2B, the insulating layer 37 exposed on the bottom face of the opening 130a and the bottom face of the second opening is etched (a first step). Next, the conductive layer 22 is etched, which is exposed after the insulating layer 37 is etched away.

For etching the insulating layer 37, preferably conditions are used that do not etch the conductive layer 22, or, etching conditions may be used in which the etching speed of the conductive layer 22 is slower than the etching speed of the insulating layer 37. Also, for etching the conductive layer 22, preferably conditions are used so that the insulating layer 35 is not etched, or, etching conditions may be used in which the etching speed of the insulating layer 35 is slower than the etching speed of the conductive layer 22. In other words, preferably etching conditions are used having etching selectivity for one of the conductive layer 22 and the insulating layer 37 with respect to the other therebeneath.

Also, when the topmost layer of the stacked body is the conductive layer 22, in step 1, the conductive layer 22 is etched away, and subsequently, in step 2, the insulating layer 35 is etched away.

Next, as illustrated in FIG. 2C, isotropic etching is performed on the mask 130 so that the width of the openings 130a and 130b is increased (step 3). If the mask 130 is an organic film, the etching can be carried out by, for example, ashing using oxygen plasma. The amount of etching of the mask 130 in the X-Y plane is set to a width that will enable the contact plug 71 to contact the end of the control gate electrode 20.

Next, as illustrated in FIG. 2D, the insulating layer 35 is etched away, which is exposed in the bottom of the enlarged openings 130a and 130b (step 1). Next, the conductive layer 22 is etched away, which is exposed after etching the insulating layer 35 (step 2). As a result, etching holes are formed in the bottom faces of the openings 130a and 130b. Also, a step is formed in the sidewalls so that the width of the step enables the contact plug 71 to contact the end of the control gate electrode 20. Next, isotropic etching is performed on the mask 130, and the width of the openings 130a and 130b is further increased (step 3).

As illustrated in FIG. 2E, by repeating the steps 1 to 3, the contact holes 131 and 133 are formed in the stacked body 120. At this stage, the width of a step 135 formed in the sidewalls of the contact hole 131 is the same as the width of a step 135 formed in the sidewalls of the contact hole 133.

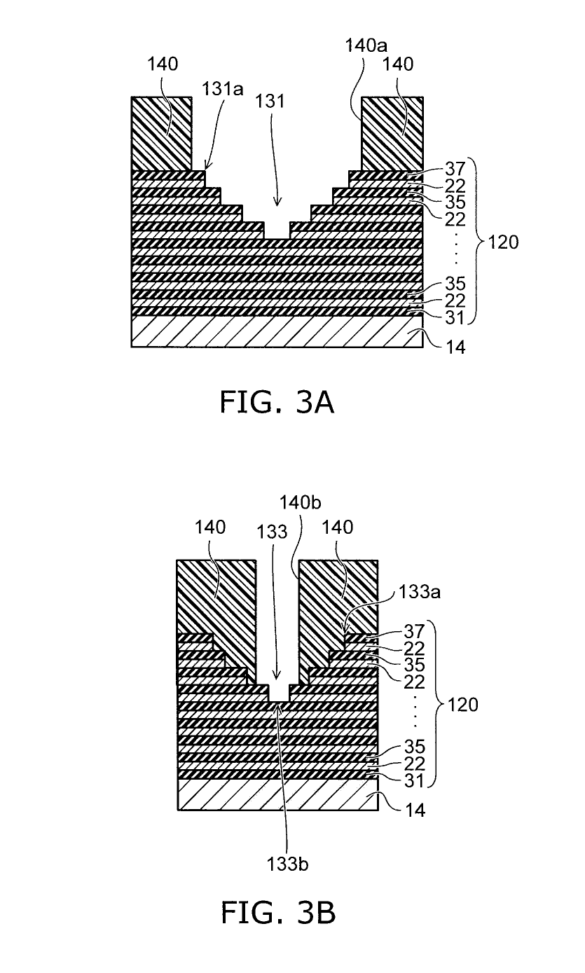

Next, the contact holes 131 and 133 are further dug down. FIGS. 3A to 7A are cross-sectional views of a portion adjacent to the memory cells, where the contact hole 131 is provided, and FIGS. 3B to 7B are cross-sectional views of another portion in the peripheral portion adjacent to the memory cell unit 1, where the contact hole 133 is provided. As illustrated in FIGS. 3A and 3B, a mask 140 (second mask) is formed on the stacked body 120. The mask 140 includes openings 140a and 140b on the contact holes 131 and 133, respectively. The mask 140 is, for example, an organic film.

The contact hole 131 is exposed in the bottom face of the opening 140a. In other words, the inside walls of the opening 140a are located on the outside of the opening edge 131a of the contact hole 131. On the other hand, the inside walls of the opening 140b are located on the inside of the opening edge 133a of the contact hole 133. Also, the bottom face 133b of the contact hole 133 is exposed in the bottom face of the opening 140b. In other words, in order to ensure that the whole area of the bottom face 133b of the contact hole 133 is exposed in the opening 140b, the opening 140b is formed so as to be wider than the bottom face 133b.

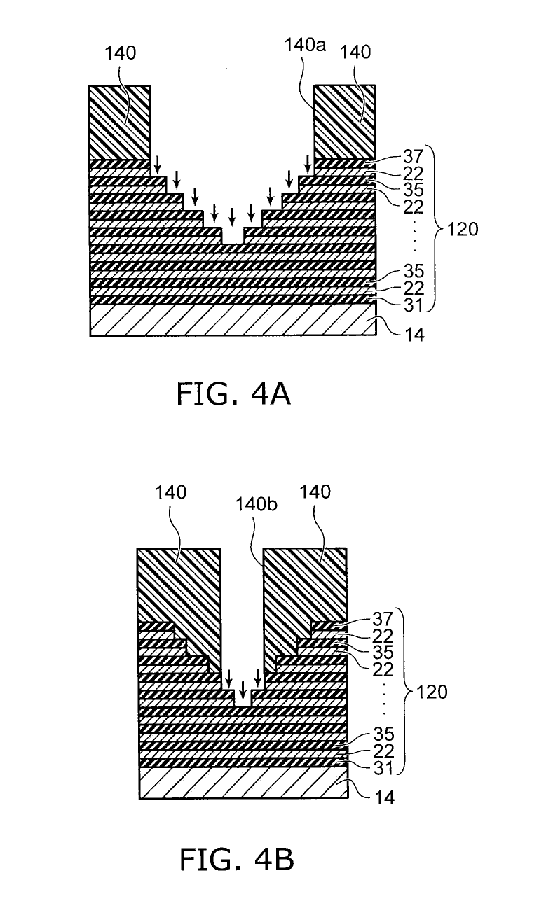

Next, as illustrated in FIGS. 4A and 4B, the insulating layer 35 is etched away, which is exposed in the bottom of the openings 140a and 140b (step 4). Then, the conductive layer 22 is etched away, which is exposed after etching the insulating layer 35 (step 5). As a result, both the contact holes 131 and 133 are made deeper by one step. The outer edge of the contact hole 131 is widened by one step. The opening edge 133a of the contact hole 133 is maintained at the same position.

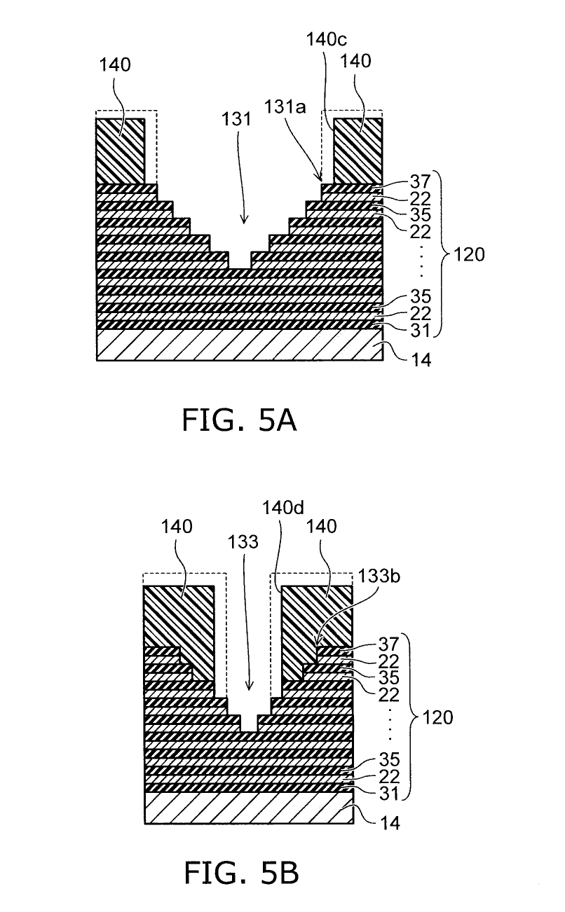

Next, as illustrated in FIGS. 5A and 5B, the mask 140 is isotropically etched, to widen the openings 140a and 140b by one step (step 6). The inside walls of the opening 140a are located on the outside of the opening edge 131a of the contact hole 131. On the other hand, the inside walls of the opening 140b are maintained to the inside of the opening edge 133a of the contact hole 133.

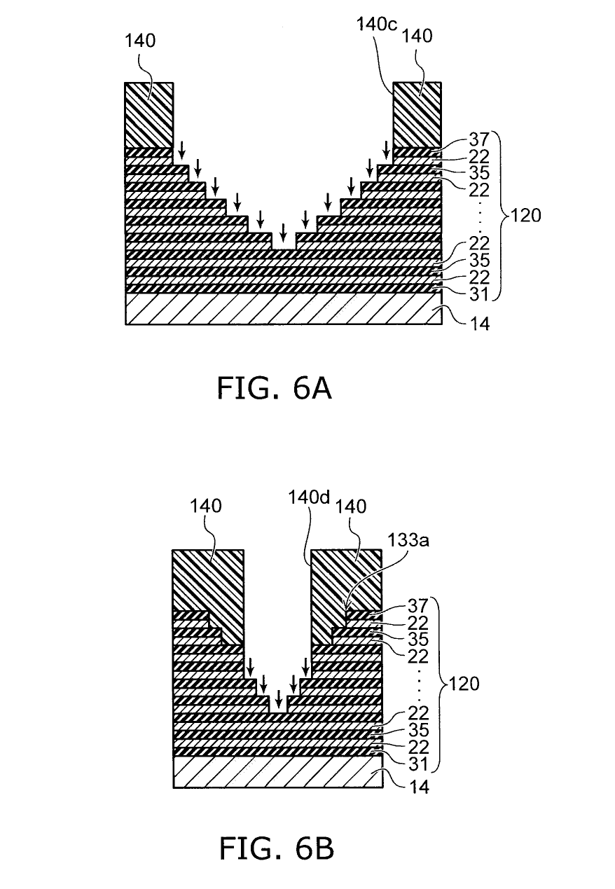

Next, as illustrated in FIGS. 6A and 6B, the insulating layer 35 is etched away, which is exposed in the bottom of the enlarged openings 140a and 140b (step 4). Then, the conductive layer 22 is etched away, which is exposed after etching the insulating layer 35 (step 5).

Next, the mask 140 is isotropically etched, to further enlarge the width of the openings 140a and 140b (step 6).

By repeating the above steps 4 and 6, the contact holes 131 and 133 are made deeper. While repeating steps 4 to 6, the position of the sidewalls of the opening 140b is preferably maintained on the inside of the opening edge 133a of the contact hole 133.

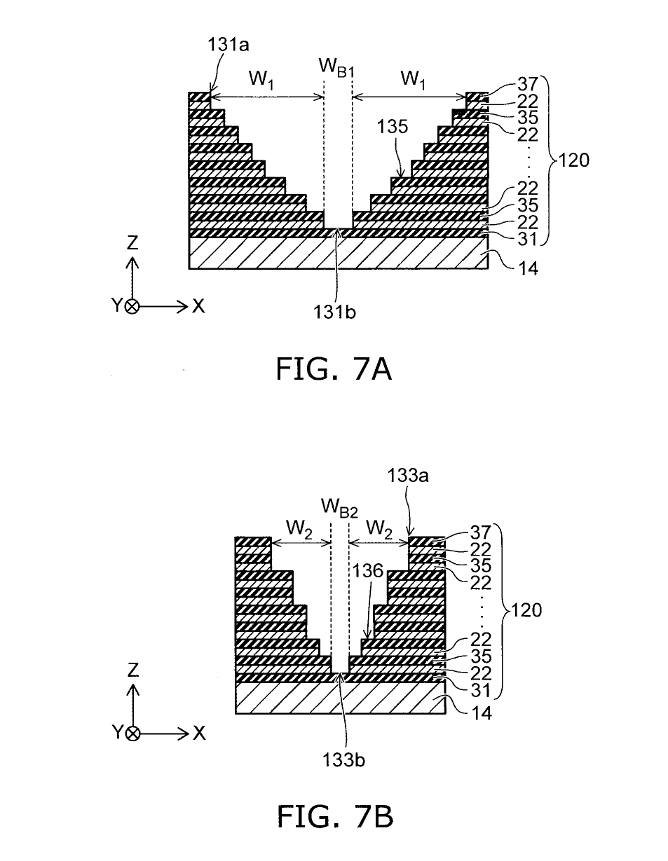

Finally, as illustrated in FIGS. 7A and 7B, all the stacked conductive layers 22 are selectively etched, and the contact holes 131 and 133 are in communication with the insulating layer 31. In this way, the opening edge 131a of the contact hole 133 is widened. Also, the sidewalls are formed in a stairs form with a plurality of steps 135 in which the ends of each of the control gate electrodes 20 are exposed.

On the other hand, in the contact hole 133, for example, the position of the opening edge 133a is maintained. Therefore, the average width of steps 136 formed in the contact hole 133 is narrower than that of the steps 135. As a result, the distance W₂ projected in the X-Y plane from the opening edge 133a of the contact hole 133 to the bottom face 133b is formed so as to be narrower than the distance W₁ projected in the X-Y plane from the opening edge 131a of the contact hole 131 to the bottom face 131b.

For example, the number of contact plugs 70 connected to the circuit 3 provided on the substrate 10 via the contact hole 133 is greater than the number of contact plugs 72 connected to the conductive layer 14 via the contact hole 131. Therefore, the width W_{B2} of the bottom face 133b of the contact hole 133 or the area of the bottom face 133b are formed greater than the width W_{B1} of the bottom face 131b of the contact hole 131 or the area of the bottom face 131b. Therefore, in this embodiment, the value of the area of the opening divided by the area of the bottom face 133b of the contact hole 133 is smaller than the value of the area of the opening divided by the area of the bottom face 131b of the contact hole 131.

As described above, in this embodiment, the contact hole 131 provided in the memory cell unit 1 is formed at the same time as the contact hole 133 provided in the peripheral portion adjacent to the memory cell unit 1. In this way, it is possible to reduce the number of manufacturing processes. For example, when the contact hole 131 is formed by the same method as the contact hole 133, the opening width of the contact hole of the peripheral portion becomes wider so the area of the chip is increased.

Therefore, in the manufacturing method according to this embodiment, the opening of the second mask for forming the contact hole 133 of the peripheral portion is made smaller, to suppress the enlargement of the contact hole 133. As a result, the contact hole 131 having the stairs shaped wall face that enables each of the control gate electrodes 20 to be contacted, and the contact hole 133 of the peripheral portion having the purpose of being in communication with the bottom face are formed at the same time, so it is possible to suppress the increase in area of the chip. As a result, it is possible to improve the manufacturing efficiency by simplifying the manufacturing process and reduce the manufacturing cost.

### SECOND EMBODIMENT

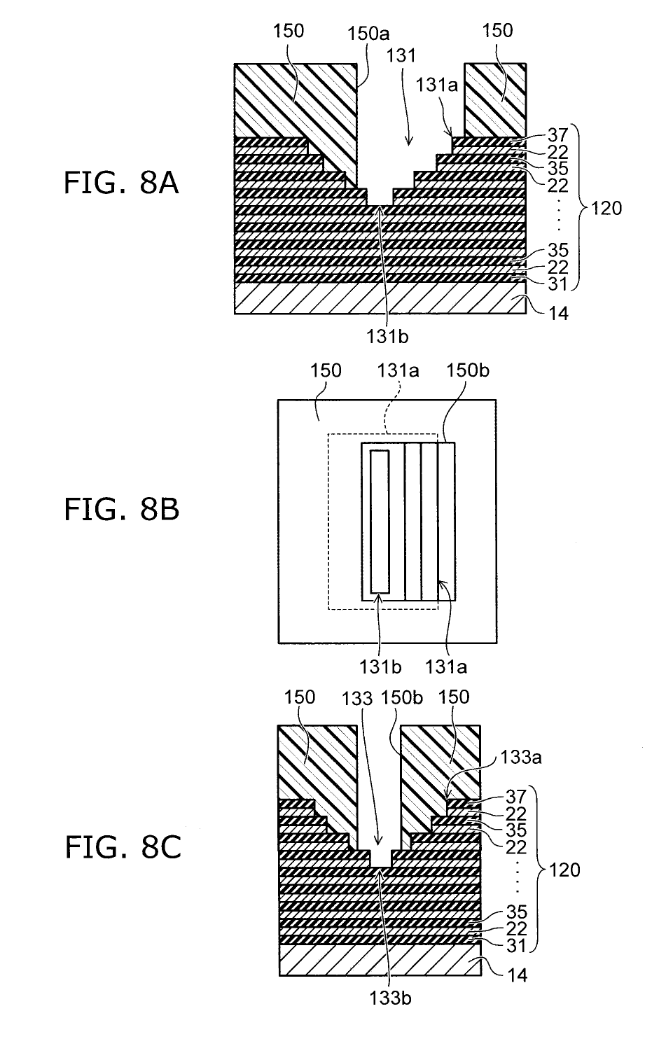

FIGS. 8 to 12 are schematic cross-sectional views illustrating the process of manufacturing a non-volatile memory device according to a second embodiment. FIG. 8A, and FIGS. 8C to 12B are schematic views illustrating the cross-section of a portion of a wafer in each of the processes. FIG. 8B is a plan view illustrating a second mask.

First, the contact holes 131 and 133 are formed in the stacked body 120 using the processes illustrated in FIGS. 2A to 2E.

Next, as illustrated in FIGS. 8A to 8C, the second mask (hereinafter, a mask 150) is formed on the top surface of the stacked body 120. The mask 150 includes openings 150a and 150b on the contact holes 131 and 133, respectively. The mask 150 is, for example, an organic film.

As illustrated in FIGS. 8A and 8B, the bottom face 131b of the contact hole 131 and a portion of the peripheral portion surrounding the contact hole 131 are exposed on the bottom face of the opening 150a.

For example, the opening edge 131a of the contact hole 131 is formed as a rectangle. Also, a portion of the opening edge 131a is exposed in the bottom face of the opening 150a on at least one side of the rectangle. For example, the opening 150a is also a rectangle, and one of its sidewalls is on the outside of the opening edge 131a. The other three sides are located on the inside of the opening edge 131a.

On the other hand, as illustrated in FIG. 8C, the sidewalls of the opening 150b are located on the inside of the opening edge 133a of the contact hole 133. The bottom face 131b of the contact hole 131 is exposed in the bottom face of the opening 150a, and the bottom face 133b of the contact hole 133 is exposed in the bottom face of the opening 150b.

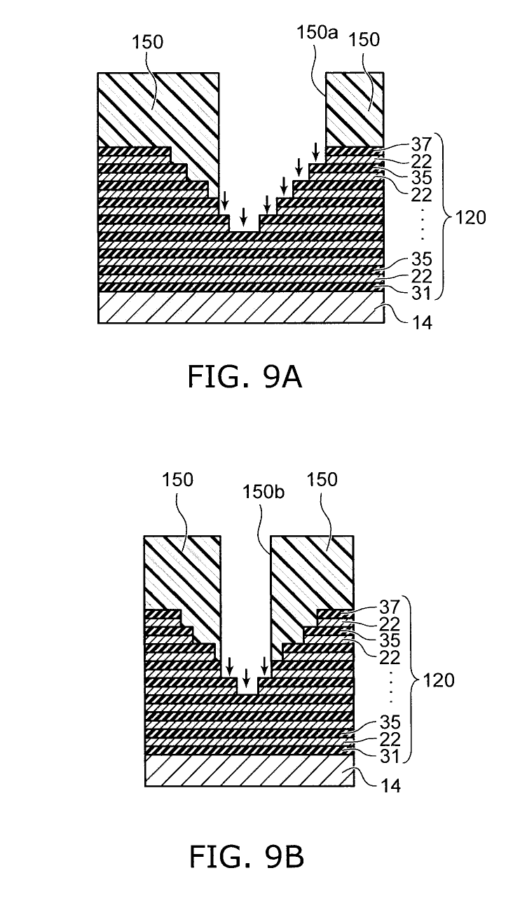

Next, as illustrated in FIGS. 9A and 9B, the insulating layer 35 is etched away, which is exposed in the bottoms of both the openings 150a and 150b (step 4). Then, the conductive layer 22 is etched away, which is exposed after etching the insulating layer 35 (step 5). As a result, both the contact holes 131 and 133 are made deeper by one step.

The outer edge of the contact hole 131 is widened by one step to the outside of the opening edge 131a exposed in the bottom face of the opening 150a. On the other hand, the position of the opening edge 131a not exposed in the bottom face of the opening 150a and the opening edge 133a of the contact hole 133 is maintained in the same position.

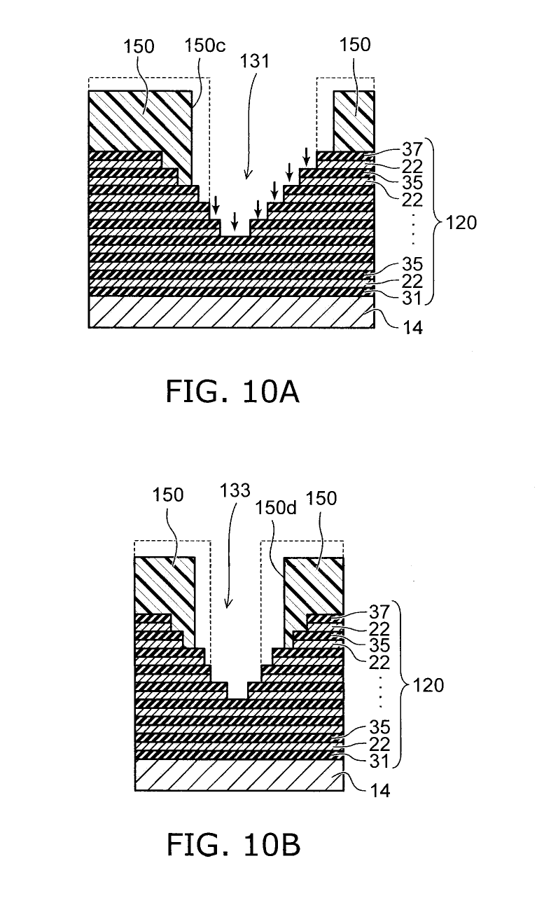

Next, as illustrated in FIGS. 10A and 10B, the mask 150 is isotropically etched, to widen the openings 150a and 150b by one step (step 6). One sidewall of the opening 150a is widened to the outside of the contact hole 131, and the opening edge 131a is exposed. The positions of the other three sidewalls of the opening 150a are maintained on the inside of the opening edge 131a of the contact hole 131 (see FIG. 8B). On the other hand, the sidewalls of the opening 150b are maintained to be located on the inside of the opening edge 133a of the contact hole 133.

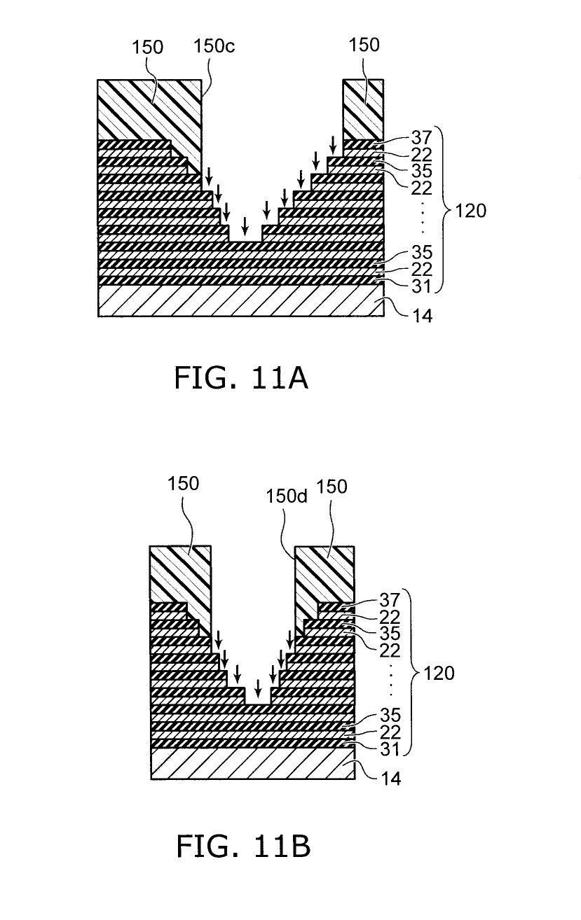

Next, as illustrated in FIGS. 11A and 11B, the insulating layer 35 is etched away, which is exposed on the bottom of both the openings 150a and 150b (step 4). Then, the conductive layer 22 is etched away, which is exposed after etching the insulating layer 35 (step 5). Next, isotropic etching is performed on the mask 150, and the width of the openings 150a and 150b is further increased (step 6).

By repeating the above steps 4 and 5, the contact holes 131 and 133 are made deeper. By repeating steps 4 to 6, preferably, one sidewall of the opening 150a is widened to be on the outside of the opening edge 131a of the contact hole 131, and the other three sidewalls are maintained to be on the inside of the opening edge 131a. Also, preferably, the positions of the sidewalls of the opening 150b are maintained to be on the inside of the opening edge 133a of the contact hole 133.

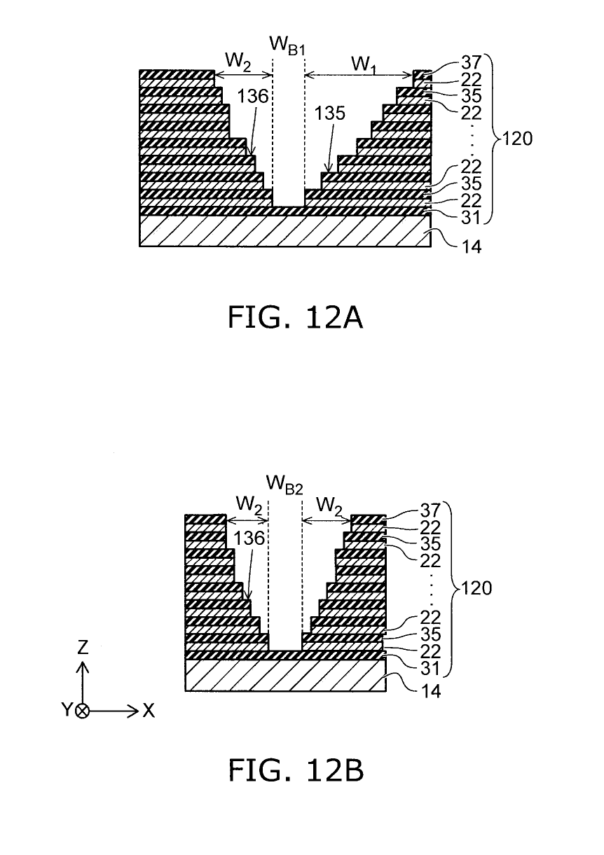

Finally, as illustrated in FIGS. 12A and 12B, all the stacked conductive layers 22 are selectively etched, and the contact holes 131 and 133 are in communication with the insulating layer 31. In the contact hole 131, one of the sides of the opening edge 131a is widened, and the other three sides are maintained at the initial position formed by steps 1 to 3. In the sidewall of the opening edge 131a that has been widened, the plurality of steps 135 is formed so that the contact plugs 71 may contact an upper face of the step 135. On the other hand, steps 136 whose average width is narrower than that of the steps 135 are formed in a stairs form in the three wall faces of the contact hole 131 that have been maintained in the initial position, and in the wall face of the contact hole 133.

In this embodiment, a portion of the opening edge 131a is enlarged in the contact hole 131 formed in the memory cell unit 1. Also, the distance W₂ between the bottom face 131b and the opening edge 131a in the portion where the wall face is not extended is formed so as to be narrower than the distance W₁ between the bottom face 131b and the opening edge 131a in the extended wall face. In this way, the opening area of the contact hole 131 is reduced, so it is possible to reduce the chip area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device, comprising:
a memory cell unit including
a plurality of control electrodes stacked on an underlying layer,
a semiconductor layer passing through the control electrodes in a first direction perpendicular to the underlying layer, and
a memory film provided between the semiconductor layer and each of the control electrodes;
an interconnection layer provided on the memory cell unit, and electrically connected to the memory cell unit; and
a control circuit provided in the underlying layer;
the memory cell unit including a first contact hole having wall faces in a stairs form, each end of the control electrodes being exposed in one of the wall faces, and
the control circuit being electrically connected to the interconnection layer via a first contact plug provided in a second contact hole, the second contact hole being provided in a peripheral portion adjacent to the memory cell unit, and including a wall face with steps.

2. The device according to claim 1, wherein the distance between an opening edge and a bottom face in the second contact hole is smaller than that in the first contact hole, when projected on a plane parallel to the underlying layer.

3. The device according to claim 1, wherein a value of an area at the opening edge divided by an area of a bottom face in the second contact hole is smaller than that in the first contact hole.

4. The device according to claim 1, wherein the first contact plug electrically connects a terminal of the circuit exposed on a bottom face of the second contact hole and a first interconnection included in the interconnection layer.

5. The device according to claim 1, wherein the second contact hole includes an insulating film embedded therein, and
the first contact plug passes through the insulating film in the first direction.

6. The device according to claim 1, wherein the interconnection layer further includes a plurality of second interconnections, and each of the second interconnections is electrically connected to any one of the control electrodes via a second contact plug provided in the first contact hole.

7. The device according to claim 6, wherein the first contact hole includes an insulating film embedded therein, and
the second contact plug passes through the insulating film in the first direction.

8. The device according to claim 1, wherein the memory cell unit further includes a conductive layer provided between the control electrode and the underlying layer, and
the conductive layer is exposed in the bottom face of the first contact hole.

9. The device according to claim 8, wherein the interconnection layer further includes a third interconnection, and the first contact hole further includes a third contact plug that electrically connects the conductive layer and the third interconnection.

10. The device according to claim 9, wherein the first contact hole includes an insulating film embedded therein, and
the third contact plug passes through the insulating film in the first direction.

11. The device according to claim 1, wherein the memory cell unit further includes an insulating layer provided between the control electrodes.

12. The device according to claim 11, wherein the insulating layer includes at least one of a silicon oxide film and a silicon nitride film.

13. The device according to claim 1, wherein the control electrode includes polycrystalline silicon.

14. The device according to claim 1, wherein the underlying layer includes a silicon substrate.

15. A method for manufacturing a non-volatile memory device, comprising:
forming a first mask having a first opening and a second opening on a stacked body that includes conductive layers and insulating layers, each conductive layer and each insulating layer being stacked alternately on a underlying layer;
forming in the stacked body a first contact hole corresponding to the first opening and a second contact hole corresponding to the second opening by repeating a first step to a third step, wherein
the first step includes a process of etching one of the conductive layer and the insulating layer exposed in a bottom face of the first opening and the bottom face of the second opening;
the second step includes a process of etching the other of the conductive layer and the insulating layer exposed in the bottom face of the first opening and the bottom face of the second opening; and
the third step includes a process of enlarging the first opening and the second opening;
forming a second mask on the stacked body in which the first contact hole and the second hole are provided, the second mask including the bottom face of the first contact hole, and, a third opening that exposes the first contact hole and a peripheral portion surrounding the first contact hole and a fourth opening located inside the second contact hole; and
making the first contact hole and the second contact hole deeper by repeating a fourth step to a sixth step, wherein
the fourth step includes the process of etching the bottom face of the third opening and one of the conductive layer and the insulating layer exposed in the bottom face of the fourth opening,
the fifth step includes the process of etching the bottom face of the third opening and the other of the conductive layer and the insulating layer exposed in the bottom face of the fourth opening, and
the sixth step includes the process of enlarging the third opening and the fourth opening.

16. The method according to claim 15, wherein the fourth opening is maintained to be a size so as not to enlarge the second contact hole.

17. The method according to claim 15, wherein the fourth opening is formed wider than the bottom face of the second contact hole.

18. The method according to claim 15, wherein the opening edge of the first contact hole is formed as a rectangle, and
the peripheral portion exposed in the third opening locates along at least one side of the rectangle.

19. The method according to claim 15, wherein the conductive layer is selectively etched with respect to the insulating layer, and
the insulating layer is selectively etched with respect to the conductive layer.

20. The method according to claim 15, wherein the first mask and the second mask are organic films.
